(19) United States
(12) Patent Application Publication
(10) Pub. No.: US 2016/0293388 A1
(43) Pub. Date: Oct. 6, 2016

(54) PNEUMATIC COUNTERBALANCE FOR ELECTRODE GAP CONTROL

(71) Applicant: Tokyo Electron Limited, Tokyo (JP)

(72) Inventors: Lee Chen, Cedar Creek, TX (US); Colin Campbell, Austin, TX (US); Merritt Funk, Austin, TX (US)

(21) Appl. No.: 15/089,011

(22) Filed: Apr. 1, 2016

Related U.S. Application Data
(60) Provisional application No. 62/142,834, filed on Apr. 3, 2015.

(51) Int. Cl. H01J 37/32

(52) U.S. Cl. CPC H01J 37/32568; H01J 37/32009; H01J 2237/334

(57) ABSTRACT

A plasma processing system for performing a plasma processing application includes a plasma processing chamber, first and second electrodes residing in the plasma processing chamber, and a pneumatic counterbalance system operatively connected to the first electrode. The pneumatic counterbalance system is configured to support and maintain a position of the first electrode during a plasma processing application for gap control. A drive assembly separate from the pneumatic counterbalance system is configured to move the first electrode with respect to the second electrode in the plasma processing chamber for gap adjustment.

### CROSS REFERENCE TO RELATED APPLICATION

Pursuant to 37 C.F.R. §1.78(a)(4), the present application claims the benefit of and priority to co-pending Provisional Application No. 62/142,834 (Attorney Docket No. TEA-058) filed on Apr. 3, 2015, and entitled PNEUMATIC COUNTERBALANCE FOR ELECTRODE GAP CONTROL, which is expressly incorporated herein by reference.

### FIELD OF THE INVENTION

This invention relates generally to plasma processing devices and methods, and more particularly to devices and methods related to controlling the gap between electrodes in a plasma processing chamber.

### BACKGROUND OF THE INVENTION

In plasma processing applications, a working gas is ionized to create charged particles, including positively- and negatively-charged ions and electrons, as well as energetic free radicals. These charged particles and free radicals can be used to modify the physical and/or chemical properties of a substrate surface, such as a semiconductor wafer. Plasma processing can be used for both adding material to, and removing material from, a substrate surface. Working gas can be ionized by applying an electric current across it, which can happen when the working gas is between electrodes of a charged circuit.

Plasma etching, for example, is a common technique used in the manufacture of integrated circuits. As part of the manufacture of integrated circuits, various layers of material are deposited on a silicon wafer substrate. By a plasma etching process, target portions of those layers can be removed. In particular, and according to known methods, free radicals created by the ionization of a working gas attack and remove portions of the layers on a silicon wafer that are not protected by a photoresist layer. Plasma etching is performed in a plasma etching chamber.

In a known configuration of a plasma etching chamber, a first electrode is positioned in a chamber and opposed from a second electrode, which is also positioned in the chamber. The first and second electrodes are part of an electric circuit and are configured to apply a current across a working gas. A silicon wafer is positioned proximate one of the electrodes, and in most cases is supported on the electrode or a holder that contains the electrode, and a processing space is defined between the electrodes. The chamber is a closed system, and air between the electrodes is evacuated (such as by a vacuum pump) as part of a preparation step in a plasma creation process. A working gas is then introduced into the evacuated processing space between the electrodes, and the circuit having the first and second electrodes is energized. Energizing the circuit causes a potential to be applied across the working gas, and the working gas is converted thereby into a plasma that can work on the silicon wafer.

The relative distance between the electrodes in a plasma etching chamber can be adjusted to alter the processing space. According to a known configuration, one of the electrodes is supported by a lead screw drive mechanism that allows the electrode to be moved toward or away from the other electrode. The lead screw drive mechanism includes a plurality of threaded lead screws connected to the moveable electrode, such as through a threaded connector plate. The lead screws, in turn, are connected to a motor-driven gear train for turning the lead screws. Rotation of the lead screws and the engagement between their threads and the threaded connector plate provides linear movement of the connector plate and therefore, the moveable electrode. Such a configuration presents substantial drawbacks, however, and is costly and complex to implement in a plasma etching chamber. Particularly, when the chamber is evacuated, the pressure differential between the evacuated processing space between the electrodes and the ambient environment places considerable pressure forces on the moveable electrode. This pressure differential can cause several thousands of pounds of pressure force to be applied to the moveable electrode. The lead screws and the connector plate and their associated threads, therefore, must be of substantial construction in order to support the connector plate and the moveable electrode and maintain them in a position under these considerable pressure forces. In addition, movement of the electrode is difficult, as the motor-driven gear train must provide sufficient rotational forces on the lead screws to overcome the considerable pressure forces created in the plasma etching chamber and acting on the moveable electrode. Accordingly, the speed at which the moveable electrode can be moved is limited.

Thus, needs exist in the plasma processing arts for improved solutions to the problems relating to the positioning and movement of electrodes in a plasma processing chamber.

### SUMMARY OF THE INVENTION

The present invention overcomes the problems and other shortcomings of the prior art plasma processing chamber systems set forth above. In particular, useful devices and methods are disclosed relating to maintaining and adjusting the gap between electrodes in a plasma processing chamber.

According to an embodiment of the invention disclosed herein, a plasma processing system for performing a plasma processing application includes a plasma processing chamber, first and second electrodes residing in the plasma processing chamber and defining an electrode gap therebetween, and a pneumatic counterbalance system operatively connected to the first electrode. The pneumatic counterbalance system is configured to support and maintain a position of the first electrode relative to the second electrode during a plasma processing application thereby controlling the electrode gap. In a further embodiment, a drive assembly separate from the pneumatic counterbalance system is configured to move the first electrode with respect to the second electrode in the plasma processing chamber to adjust the electrode gap. In yet a further embodiment, a force transmission assembly is configured to connect the pneumatic counterbalance system and the first electrode.

According to another embodiment of the invention disclosed herein, a method of maintaining a position of a moveable first electrode with respect to a stationary second electrode in a plasma processing chamber during a plasma processing application includes applying a counterbalance force to the first electrode equal in magnitude but opposite in direction to the forces acting on the first electrode during the plasma processing application. The counterbalance force is applied using a pneumatic counterbalance system that includes an air cylinder having a shaft operatively connected to the first electrode. Applying the counterbalance force may include providing air from an air supply to an air cylinder of the pneumatic counterbalance system.

According to another embodiment of the invention disclosed herein, a method of moving a moveable first electrode with respect to a stationary second electrode in a plasma processing chamber to adjust the electrode gap therebetween includes supporting the first electrode by a pneumatic counterbalance system operatively connected to the first electrode, and moving the first electrode by a drive assembly operatively connected to the first electrode and separate from the pneumatic counterbalance system.

According to yet another embodiment of the invention disclosed herein, a combination for use with a plasma processing chamber having a moveable first electrode and a stationary second electrode residing therein includes a pneumatic counterbalance system configured to be operatively connected to the moveable first electrode to support and maintain a position of the moveable first electrode with respect to the stationary second electrode in the plasma processing chamber, and a drive assembly configured to be operatively connected to and to move the moveable first electrode with respect to the stationary second electrode in the plasma processing chamber. The drive assembly is separate from the pneumatic counterbalance system.

While the present invention will be described in connection with certain embodiments, it will be understood that the present invention is not limited to these embodiments. To the contrary, this invention includes all alternatives, modifications, and equivalents as may be included within the spirit and scope of the present invention.

### BRIEF DESCRIPTION OF THE FIGURES

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1 is a schematic view of a plasma processing system having a plasma processing chamber and a pneumatic counterbalance system according to an embodiment of the present invention.

FIG. 2 is a partial cross-sectional view of the plasma processing system of FIG. 1 taken generally along line 2-2 in FIG. 3 and showing the pneumatic counterbalance system connected to a force transmission assembly and a moveable first electrode, as well as a drive assembly for causing movement of the moveable first electrode.

FIG. 3 is an isometric view of the plasma processing system of FIGS. 1 and 2 and showing some of the features of the plasma processing chamber in partial phantom view.

### DETAILED DESCRIPTION

In the following description, to facilitate a thorough understanding of the invention and for purposes of explanation and not limitation, specific details are set forth, such as a particular embodiment of the plasma processing system and various descriptions of the system components. However, it should be understood that the invention may be practiced with other embodiments that depart from these specific details. Nonetheless, it should be appreciated that, contained within the description are features which, notwithstanding the inventive nature of the general concepts being explained, are also of an inventive nature.

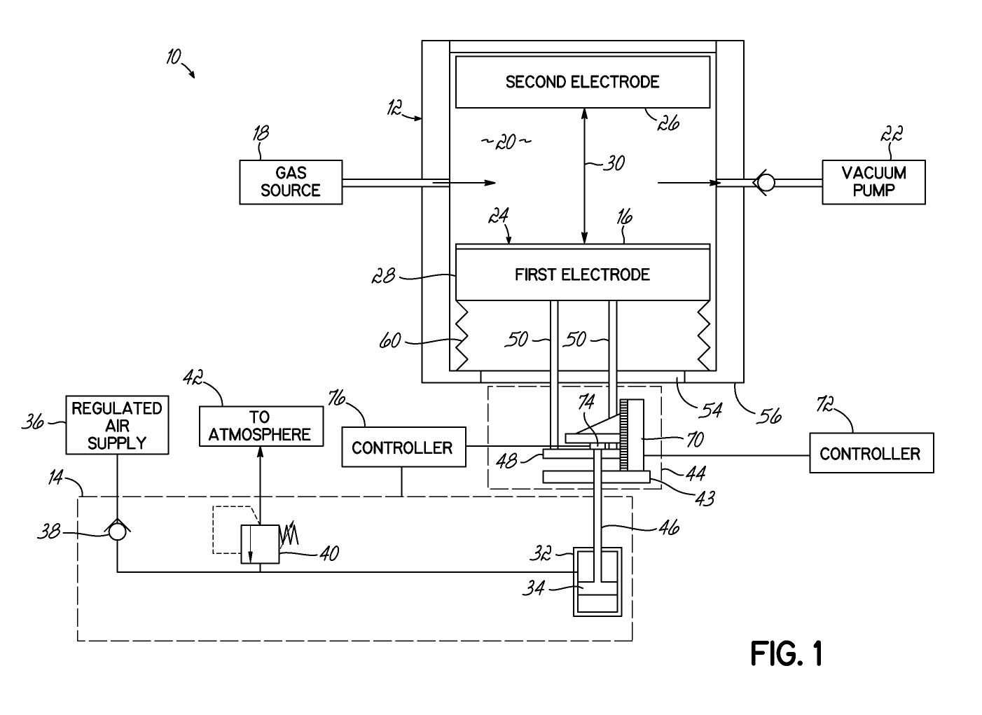

Referring now to the figures, and beginning with FIG. 1, a plasma processing system 10 according to an embodiment of the present invention is shown and described in detail. The plasma processing system 10 includes a plasma processing chamber generally indicated by the numeral 12, and a pneumatic counterbalance system generally indicated by the numeral 14. The plasma processing system 10 is configured to perform plasma-assisted or plasma-activated processing of a substrate 16 (such as a silicon wafer) positioned within the chamber 12.

The plasma processing system 10 further includes a gas feed supply 18 fluidically coupled to the chamber 12 and configured to supply one or more working gases to a processing space 20 within the chamber 12. A vacuum pump 22 is fluidically connected to the processing space 20 and is configured to draw a vacuum on, and evacuate or partially evacuate, the contents of the processing space 20.

Two electrodes 24, 26 reside within the chamber 12. The first electrode 24 may be incorporated into, or comprise, a substrate support 28. The substrate 16 is supported on the substrate support 28, and the substrate support 28 may include an electrostatic chuck or other suitable device for holding the substrate 16. The second electrode 26 is positioned within the chamber 12 and opposed from the substrate 16 and the first electrode 24. The first and second electrodes 24, 26 can be part of any suitable circuit for performing plasma processing applications. The processing space 20 is generally defined between the first and second electrodes 24, 26. The distance between the first and second electrodes 24, 26 defines an electrode gap 30. As will be explained more fully below, the first electrode 24 is moveable within the chamber 12 with respect to the second electrode 26, thereby providing for adjustment of the electrode gap 30. It will be appreciated that the substrate 16 could alternatively be supported by a substrate support incorporated into or included with the second electrode 26, which is stationary in the chamber 12. Alternatively, it may be appreciated that the second electrode 26 may be moveable with respect to the first electrode 24, which may be stationary and supporting the substrate 16. While the first electrode 24 is shown as the “bottom” electrode in the chamber 12, and second electrode 26 as the “top” electrode, it may also be appreciated that either of the first electrode 24 or second electrode 26 may be considered the “top” electrode, with the other being considered the “bottom” electrode. Thus, the terms “first”, “second”, “top”, and “bottom” are used solely to distinguish one electrode from the other and are not limited to the particular electrode arrangement shown and described in FIGS. 1-3.

The pneumatic counterbalance system 14 is configured to support and maintain the position of the first electrode 24 in the chamber 12 relative to the second electrode 26. Thus, the pneumatic counterbalance system 14 is used to maintain the electrode gap 30. The pneumatic counterbalance system 14 may include an air cylinder 32 having a moveable piston 34. A regulated air supply 36 is fluidically coupled with and provides a supply of air to the air cylinder 32 to act on the piston 34. A check valve 38 is interposed between the air supply 36 and the air cylinder 32. A pressure relief valve 40 is also interposed between the air supply 36 and the air cylinder 32 to allow for release of air to the atmosphere 42. Operation of the valves 38, 40 will be explained more fully below. The air cylinder 32 can be mounted to a mounting plate 43.

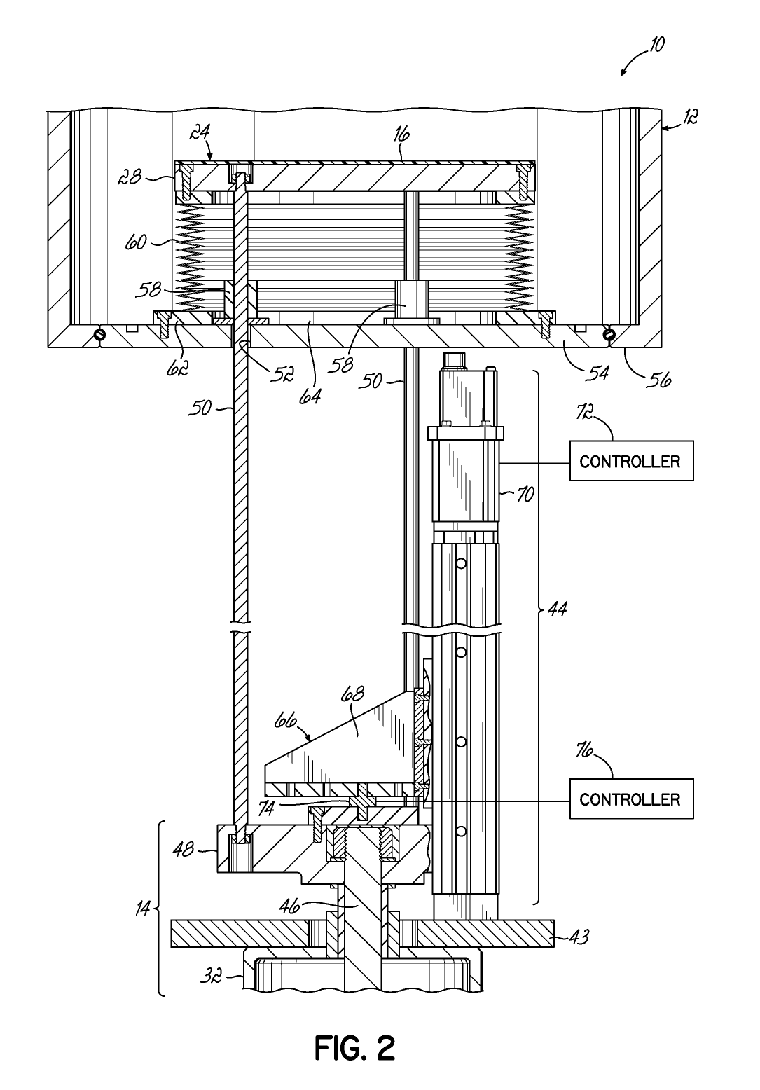

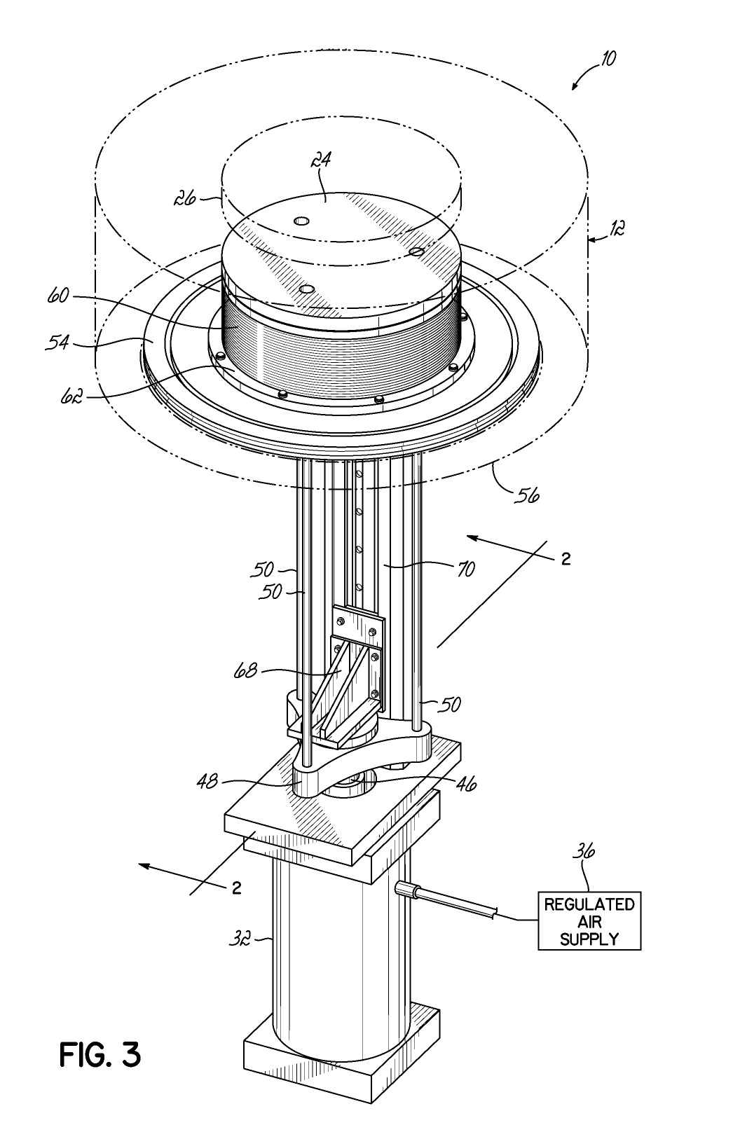

The pneumatic counterbalance system 14 is operatively connected to, and acts on, the first electrode 24 through a force transmission assembly 44. With reference to FIGS. 2 and 3, where FIG. 2 is taken generally along line 2-2 of FIG. 3, an air cylinder shaft 46 is connected to the piston 34 (FIG. 1) of the air cylinder 32 and to a coupling plate 48 outside the air cylinder 32. Force transmission shafts 50 are connected at one end to the coupling plate 48 and at the other end to the first electrode 24. In particular, the force transmission shafts 50 extend from the coupling plate 48 and through openings 52 in a vacuum flange 54 at an end 56 of the chamber 12 to connect with the first electrode 24. Linear bearings 58 may be provided to aid in the linear movement of the transmission shafts 50 and may be provided inside the chamber 12 adjacent the vacuum flange 54, as shown. A bellows device 60 may be provided that extends generally between the first electrode 24 and the vacuum flange 54, or to a plate 62 positioned thereon inside the chamber 12 and between the vacuum flange 54 and the first electrode 24. If such a plate 62 is used, it includes one or more openings 64 through which the transmission shafts 50 and the linear bearings 58 extend. Optionally, the linear bearings 58 may also be positioned generally between the plate 62 and the first electrode 24.

A drive assembly 66 is connected to the coupling plate 48 and is configured for moving the coupling plate 48, which causes movement of the transmission shafts 50 and the first electrode 24. In particular, the drive assembly 66 includes a drive arm 68 connected to the coupling plate 48 and to a linear drive mechanism 70. The linear drive mechanism 70 is configured to cause movement of the coupling plate 48 through the connection of the drive arm 68 to the force transmission assembly 44. Particularly, activation of the drive mechanism 70 causes movement that is transferred through the drive arm 68 to the coupling plate 48. Movement of the coupling plate 48 thereby causes movement of the transmission shafts 50 which are connected thereto. And movement of the transmission shafts 50 causes movement of the first electrode 24. Specifically, the drive mechanism 70 can cause the first electrode 24 to be selectively moved toward or away from the second electrode 26, thereby providing for adjustment of the electrode gap 30. The drive mechanism 70 is configured to make fine position adjustments and can include, for example, a linear stepper motor, or any other suitable device for causing movement of the drive arm 68, which might also include a driven lead screw arrangement, a linear actuator, a linear rail, and the like. The drive mechanism 70 is connected to a controller 72 having appropriate tool software and controls to activate and control the drive mechanism 70. Thereby, the position of the first electrode 24 can be precisely controlled. The drive mechanism 70 can be positioned between the mounting plate 43 and the vacuum flange 54, and optionally mounted to either or both.

A load sensor 74 is interposed between the drive arm 68 and the coupling plate 48 for sensing any relative loads therebetween. The load sensor 74 is connected to a controller 76, which controller 76 is also connected to the pneumatic counterbalance system 14, as shown in FIG. 1. If a relative load exists between the drive arm 68 and the coupling plate 48, the pneumatic counterbalance system 14 can be adjusted to eliminate or reduce the relative load, such as by providing additional air to the air cylinder 32, or by releasing air therefrom.

In use, the pneumatic counterbalance system 14 is used to support the first electrode 24 and to maintain its position with respect to the second electrode 26. In particular, the pneumatic counterbalance system 14 provides a counterbalance force to the forces acting on the first electrode 24. When the vacuum pump 22 draws a vacuum on the processing space 20, a low pressure condition is created in the processing space 20. This tends to cause forces to be exerted on the first electrode 24 (which is moveable) toward the second electrode 26. The pneumatic counterbalance system 14 is configured to balance this, and a counterbalancing force is applied to the first electrode 24 to prevent it from moving with respect to the second electrode 26. In particular, the air supply 36 provides air to the air cylinder 32 so that its piston 34 through the shaft 46 exerts a force on the force transmission assembly 44 to balance the forces on the first electrode 24. The forces on the first electrode 24 can include forces created by the low pressure vacuum, as well as the weight of the first electrode 24 and items attached thereto, such as the substrate 16 and the force transmission assembly 44. Air is provided by the air supply 36 until the pneumatic counterbalance system 14 balances the net load on the first electrode 24. The check valve 38 is configured so an appropriate pressure or supply of air is provided from the air supply 36 to the air cylinder 32 to create the balancing force. If the first electrode 24 is moved away from the second electrode 26, the check valve 38 can open to allow additional air to flow to the air cylinder 32 to counterbalance a corresponding increase in pressure on the first electrode 24. Alternatively, if the first electrode 24 is moved toward the second electrode 26, the pressure relief valve 40 can open to allow air to escape to the atmosphere 42 to counterbalance a corresponding decrease in pressure on the first electrode 24.

With the forces on the first electrode 24 effectively balanced by the pneumatic counterbalance system 14, there are essentially no net forces acting on it. As a result, the drive mechanism 70 is free to precisely adjust the position of the first electrode 24 with respect to the second electrode 26 with very small additional force. That is, the drive mechanism 70 does not have to overcome the substantial pressure forces created by the vacuum, and is dedicated solely to moving the first electrode 24. The drive mechanism 70 does not support or maintain the position of the first electrode 24. Thus, the pneumatic counterbalance system 14 provides for the efficient control of the electrode gap 30.

The first electrode 24 can be supported, and the position of the first electrode 24 with respect to the second electrode 26 can be maintained, in the chamber 12 during a plasma processing application. In particular, a counterbalance force equal in magnitude to, but opposite in direction to, the forces acting on the first electrode 24 during the plasma processing application is applied to the first electrode 24 by the pneumatic counterbalance system 14. In particular, the shaft 46 of the air cylinder 32 is operatively connected to the first electrode 24 (through the force transmission assembly 44), and air provided to the air cylinder 32 acts on the piston 34 of the air cylinder 32 to provide the counterbalance force.

In addition, the first electrode 24 may be moved with respect to the second electrode 26 to adjust the electrode gap 30. The first electrode 24 is supported by the pneumatic counterbalance system 14 (as disclosed above), and the drive assembly 66 (which is operatively connected to the first electrode 24 through the force transmission assembly 44) can move the first electrode 24.

Some of the features of the plasma processing system 10 might also be incorporated into an existing plasma processing system. For example, an existing plasma processing system might not include features for moving one electrode with respect to another electrode, or might include an old lead screw drive mechanism. Any or all of the pneumatic counterbalance system 14, the force transmission assembly 44, and the drive assembly 66 could be used with an existing plasma processing system. For example, the combination of a pneumatic counterbalance system and a drive assembly, each being configured to be operatively connected to a moveable first electrode may be provided for use with an existing plasma processing system for moving that electrode relative to the other. Further, features of the plasma processing chamber and its electrodes of the existing plasma processing system can be replaced in order to incorporate components disclosed herein in association with the plasma processing system 10.

It will be appreciated that the teaching contained herein offer several advantages for plasma processing systems. For one, a pneumatic counterbalance system controls the positioning of a moveable electrode and balances the forces acting on the moveable electrode. A drive assembly is then free to adjust the position of the moveable electrode without having to overcome the substantial pressure forces created by the vacuum in a plasma processing chamber. This allows a moveable electrode arrangement to be introduced into new and larger plasma processing chambers where pressures can be considerable. In addition, a pneumatic counterbalance system, force transmission assembly and drive assembly such as disclosed herein can be incorporated into existing plasma processing systems, providing a replacement for prior lead screw drive mechanisms and motor-driven gear trains, thereby extending the useful life of or improving an existing plasma processing system. Moreover, in conjunction with a pneumatic counterbalance system, a drive mechanism can precisely control the position of a moveable electrode.

While the present invention has been illustrated by description of various embodiments and while those embodiments have been described in considerable detail, those skilled in the art will readily appreciate that many modifications are possible in the exemplary embodiment without materially departing from the novel teachings and advantages of this invention. The invention in its broader aspects is therefore not limited to the specific details and illustrative examples shown and described. Accordingly, departures may be made from such details without departing from the scope of the present invention.

What is claimed is:

1. A plasma processing system for performing a plasma processing application, comprising:
a plasma processing chamber;
first and second electrodes residing in the plasma processing chamber and defining an electrode gap therebetween; and
a pneumatic counterbalance system operatively connected to the first electrode and configured to support and maintain a position of the first electrode relative to the second electrode during a plasma processing application thereby controlling the electrode gap.

2. The plasma processing system of claim 1, further comprising a drive assembly operatively connected to the first electrode and configured to move the first electrode with respect to the second electrode to adjust the electrode gap, the drive assembly being separate from the pneumatic counterbalance system.

3. The plasma processing system of claim 2, further comprising a force transmission assembly connecting the pneumatic counterbalance system and the first electrode.

4. The plasma processing system of claim 3, wherein the drive assembly is connected to the force transmission assembly.

5. The plasma processing system of claim 4, wherein the pneumatic counterbalance system includes an air cylinder having a piston and a shaft extending from the piston, and further wherein the shaft is connected to the force transmission assembly.

6. The plasma processing system of claim 5, wherein the force transmission assembly includes a coupling plate and the shaft is connected to the coupling plate.

7. The plasma processing system of claim 6, wherein the force transmission assembly further includes transmission shafts connected to the coupling plate and the first electrode.

8. The plasma processing system of claim 7, wherein the drive assembly is connected to the coupling plate.

9. The plasma processing system of claim 8, wherein the drive assembly includes a linear stepper motor.

10. A method of maintaining a position of a moveable first electrode with respect to a stationary second electrode in a plasma processing chamber during a plasma processing application, comprising:
applying a counterbalance force to the first electrode equal in magnitude but opposite in direction to the forces acting on the first electrode during the plasma processing application using a pneumatic counterbalance system comprising an air cylinder having a shaft operatively connected to the first electrode.

11. The method of claim 10, wherein applying a counterbalance force includes providing air from an air supply to the air cylinder of the pneumatic counterbalance system.

12. A method of moving a moveable first electrode with respect to a stationary second electrode in a plasma processing chamber to adjust the electrode gap therebetween, comprising:
supporting the first electrode by a pneumatic counterbalance system operatively connected to the first electrode; and
moving the first electrode by a drive assembly operatively connected to the first electrode and separate from the pneumatic counterbalance system.

13. The method of claim 12, wherein supporting the first electrode includes applying a counterbalance force to the first electrode equal in magnitude but opposite in direction to the forces acting on the first electrode during the plasma processing application.

14. The method of claim 13, wherein applying a counterbalance force to the first electrode includes providing air from an air supply to an air cylinder of the pneumatic counterbalance system, the pneumatic counterbalance system including a piston and a shaft connected to the piston and operatively connected to the first electrode.

15. The method of claim 13, wherein moving the first electrode includes moving a force transmission assembly connected to the first electrode.

16. For use with a plasma processing chamber having a moveable first electrode and a stationary second electrode residing therein, a combination comprising:
a pneumatic counterbalance system configured to be operatively connected to the moveable first electrode to support and maintain a position of the moveable first electrode with respect to the stationary second electrode in the plasma processing chamber; and
a drive assembly configured to be operatively connected to and to move the moveable first electrode with respect to the stationary second electrode in the plasma processing chamber, the drive assembly being separate from the pneumatic counterbalance system.

17. The combination of claim 16, wherein the pneumatic counterbalance system includes an air cylinder having a piston and a shaft connected to the piston, the shaft being configured to be operatively connected to the moveable first electrode in the plasma processing chamber.

18. The combination of claim 17, further comprising a force transmission assembly configured to be connected to the moveable first electrode in the plasma processing chamber, the force transmission assembly being further configured to be connected to the shaft of the air cylinder.

19. The combination of claim 18, wherein the drive assembly is configured to be connected to the force transmission assembly, and wherein the drive assembly includes a drive mechanism configured for causing movement of the force transmission assembly.

20. The combination of claim 19, wherein the drive mechanism includes a linear stepper motor.
